(19) United States
(12) Patent Application Publication
(10) Pub. No.: US 2026/0370199 A1
(43) Pub. Date: Nov. 19, 2026

(54) SIGNAL AMPLIFICATION DEVICE AND ELECTRONIC APPARATUS INCLUDING THE SAME

(71) Applicant: SAMSUNG ELECTRONICS CO., LTD., Suwon-si (KR)

(72) Inventors: Jaeyeon JEONG, Suwon-si (KR); Ockgoo LEE, Busan (KR); Munsu JEONG, Busan (KR); Chanhong PARK, Suwon-si (KR); Hyunchul PARK, Suwon-si (KR)

(73) Assignees: SAMSUNG ELECTRONICS CO., LTD., Suwon-si (KR); PUSAN NATIONAL UNIVERSITY INDUSTRY-UNIVERSITY COOPERATION FOUNDATION, Busan (KR)

(21) Appl. No.: 19/446,111

(22) Filed: Jan. 12, 2026

(30) Foreign Application Priority Data
May 19, 2025 (KR) 10-2025-0064730

(51) Int. Cl. H03F 3/60; H03F 1/56; H03F 3/24

(52) U.S. Cl. CPC H03F 3/604; H03F 1/56; H03F 3/245; H03F 2200/204; H03F 2200/451

(57) ABSTRACT

A signal amplification device includes a separator circuit configured to separate an input signal into a first sub-signal and a second sub-signal; amplifiers configured to amplify the sub-signals, and output amplified signals; a directional coupler; and a capacitor connected to an isolated port of the directional coupler. The directional coupler is configured to: receive a first amplified signal via a coupled port of the directional coupler; receive a second amplified signal via a through port of the directional coupler; and output an output signal generated by coupling the first amplified signal to the second amplified signal via an input port of the directional coupler.

### CROSS-REFERENCE TO RELATED APPLICATION

This application claims priority under 35 U.S.C. § 119 to Korean Patent Application No. 10-2025-0064730, filed on May 19, 2025, in the Korean Intellectual Property Office, the disclosure of which is incorporated by reference herein in its entirety.

### BACKGROUND

The present disclosure relates to a signal amplification device and an electronic apparatus including the signal amplification device, and more particularly, to a device that divides and amplifies an input signal and linearly couples the divided signals to each other in order to achieve high amplification efficiency.

An operation of a power amplifier (hereinafter, an amplifier) below saturation power so as to maintain linearity of the amplifier is referred to as back-off.

Modern communication systems utilize signals having a high peak to average power ratio (PAPR) so as to transmit massive amounts of data at high speeds.

The signals having the high PAPR are generated by the amplifier operating in a back-off condition, which causes a degradation of the amplification efficiency of the amplifier. Therefore, research and development has been conducted on amplifiers having improved amplification efficiency for signals with high PAPR.

### SUMMARY

One or more embodiments provide a device having an outphasing architecture capable of achieving high amplification efficiency even under a back-off condition.

One or more embodiments also provide a device capable of amplifying the magnitude of an input signal, wherein the device outputs an output signal having the same shape as the input signal.

One or more embodiments also provide a device configured to achieve impedance matching to reduce power loss due to reflection and loss of signals.

One or more embodiments also provide a device configured to include no resistors to reduce power loss due to heat generation.

One or more embodiments also provide a device capable of coupling signals to each other based on a directional coupler to increase the degree of integration.

Technical objectives are not limited to those stated above, and other technical objectives not described herein are clearly understood by those skilled in the art from the following descriptions.

According to an aspect of an embodiment, a signal amplification device includes: a separator circuit configured to separate an input signal into a first sub-signal and a second sub-signal; a first amplifier configured to amplify the first sub-signal, and output a first amplified signal; a second amplifier configured to amplify the second sub-signal, and output a second amplified signal; a directional coupler; and a capacitor connected to an isolated port of the directional coupler. The directional coupler is configured to: receive the first amplified signal via a coupled port of the directional coupler; receive the second amplified signal via a through port of the directional coupler; and output an output signal generated by coupling the first amplified signal to the second amplified signal via an input port of the directional coupler.

According to another aspect of an embodiment, an electronic apparatus includes a radio frequency (RF) transmitter. The RF transmitter includes: a separator circuit configured to separate an input signal into a plurality of sub-signals; an amplifier circuit configured to amplify each of the plurality of sub-signals, and output a plurality of amplified signals; a coupling circuit including a directional coupler configured to couple the plurality of amplified signals to each other to generate an output signal, and output the output signal; and an antenna configured to transmit the output signal. The directional coupler includes a plurality of first ports configured to receive the plurality of amplified signals, a second port configured to output the output signal, and a third port to which impedance is connected.

According to another aspect of an embodiment, a signal amplification device includes: a conversion circuit configured to generate a first sub-signal based on a first input signal, and a second sub-signal based on a second input signal; a first amplifier configured to amplify the first sub-signal, and output a first amplified signal; a second amplifier configured to amplify the second sub-signal, and output a second amplified signal; a directional coupler; and a capacitor connected to an isolated port of the directional coupler. The directional coupler is configured to: receive the first amplified signal via a coupled port of the directional coupler; receive the second amplified signal via a through port of the directional coupler; and output an output signal generated by coupling the first amplified signal to the second amplified signal via an input port of the directional coupler.

### BRIEF DESCRIPTION OF DRAWINGS

The above and other aspects will be more apparent from the following description of embodiments, taken in conjunction with the accompanying drawings, in which:

FIG. 1 is a diagram showing a configuration of a signal amplification device according to an embodiment;

FIG. 2 is a diagram illustrating an outphasing architecture according to an embodiment;

FIG. 3 is a diagram showing a configuration of a signal amplification device according to another embodiment;

FIG. 4 is a diagram showing the structure of a directional coupler according to an embodiment;

FIGS. 5A and 5B are diagrams illustrating relationships between performance of an amplifier and outphasing angles, according to an embodiment;

FIG. 6 is a diagram showing a configuration of a signal amplification device according to another embodiment;

FIG. 7 is a diagram showing a configuration of an electronic apparatus including a signal amplification device according to an embodiment;

FIG. 8 is a diagram showing a configuration of a signal amplification device according to an embodiment;

FIGS. 9A and 9B are diagrams comparing the degrees of integration between devices according to an embodiment and devices according to a comparative example;

FIG. 10 is a flowchart illustrating a signal amplification method according to an embodiment; and

FIG. 11 is a flowchart illustrating a signal amplification method according to another embodiment.

### DETAILED DESCRIPTION

Hereinafter, embodiments are described in detail with reference to the accompanying drawings. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure.

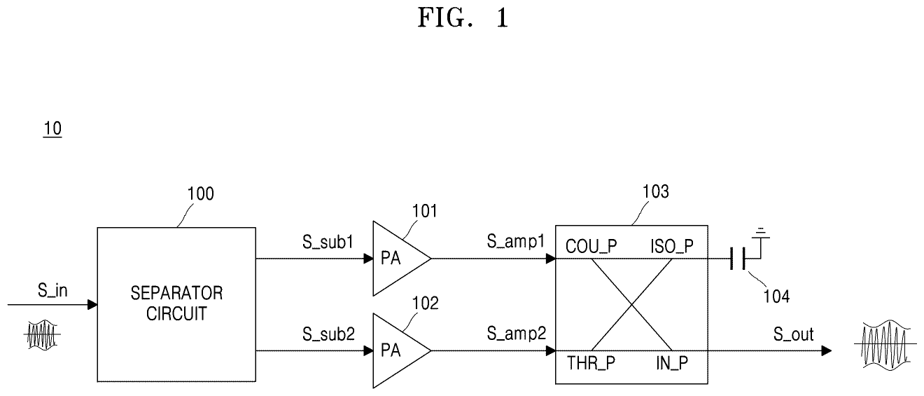

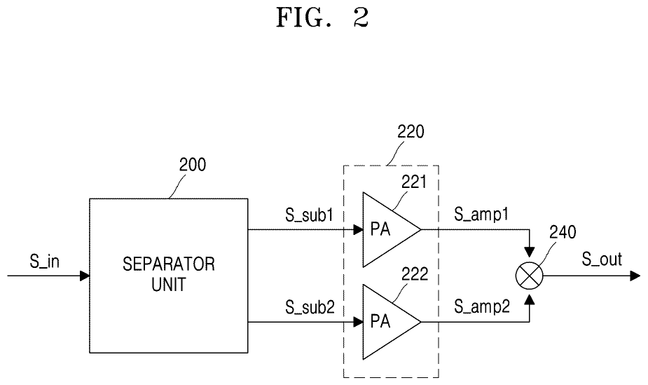

FIG. 1 is a diagram showing a configuration of a signal amplification device 10 according to an embodiment. FIG. 2 is a diagram illustrating an outphasing architecture according to an embodiment.

The signal amplification device 10 according to an embodiment may include a separator circuit 100, a first power amplifier 101 (hereinafter, referred to as the first amplifier 101), a second power amplifier 102 (hereinafter, referred to as the second amplifier 102), a directional coupler (e.g., directional coupler circuit) 103, and a capacitor 104. All of the blocks illustrated in FIG. 1 are not required components. In another embodiment, some of the blocks in FIG. 1 may be changed or deleted, and other blocks may be added thereto. Also, the components illustrated in FIG. 1 represent functionally distinct elements, but one or more of the components may be integrated with each other in an actual physical environment. In this specification, a circuit including a directional coupler (hereinafter referred to as a “directional coupler circuit”) may be referred to as a “directional coupler.”

The signal amplification device 10 may have an outphasing architecture and may amplify an input signal S_in and output an output signal S_out. The outphasing architecture represents an architecture that is operated by an outphasing method to improve the amplification efficiency of an amplifier. The outphasing architecture may be utilized in stations of a wireless communication system, such as base stations and mobile stations of a cellular communication system, mobile units and access points of a wireless local area network (WLAN), and/or other types of wireless communication systems.

Referring to FIG. 2, the outphasing architecture may include a separator unit 200, an amplifier unit 220, and a coupling unit 240. The amplifier unit 220 may include a plurality of amplifiers 221 and 222 corresponding to a plurality of sub-signals S_sub1 and S_sub2, respectively. In the outphasing method, the separator unit 200 separates the input signal S_in into the plurality of sub-signals S_sub1 and S_sub2 having adjusted phases or amplitudes, the amplifier unit 220 amplifies the power of each of the plurality of sub-signals S_sub1 and S_sub2 and generates a plurality of amplified signals S_amp1 and S_amp2, and the coupling unit 240 synthesizes the plurality of amplified signals S_amp1 and S_amp2 and supplies the output signal S_out to a load. The outphasing method may adjust the phase or amplitude of the input signal S_in and output the output signal S_out having high amplification efficiency.

The signal amplification device 10 may be configured in an outphasing architecture to increase amplification efficiency. Thus, even under a back-off condition, the amplifiers (see 101 and 102 of FIG. 1) may operate at high efficiency.

The separator circuit 100 may be configured to receive the input signal S_in, separate the input signal S_in into the plurality of sub-signals S_sub1 and S_sub2, and output the same. The separator circuit 100 may be configured to separate the input signal S_in into the plurality of sub-signals S_sub1 and S_sub2 such that the phase or amplitude of the input signal S_in is adjusted to conform to the characteristics of a directional coupler. In this case, the characteristics of the directional coupler may include characteristic impedance, the phase difference between a through port and a coupled port of the directional coupler, even mode impedance (Z₀ₑ), odd mode impedance (Z₀ₒ), and the length of an internal transmission line. Thus, the separator circuit 100 may be configured to, based on the phase difference between a through port and a coupled port of the directional coupler, even mode impedance (Z₀ₑ), odd mode impedance (Z₀ₒ), and the length of an internal transmission line, separate the input signal S_in into the plurality of sub-signals S_sub1 and S_sub2 such that the phase or amplitude of the input signal S_in is adjusted to conform to the characteristic impedance.

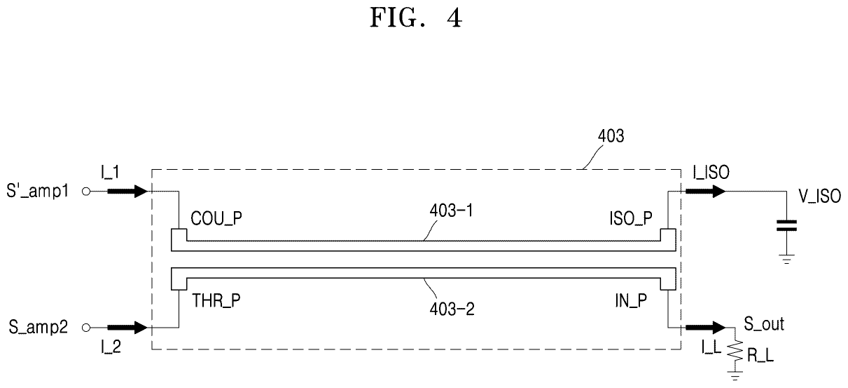

The output signal S_out is generated by coupling signals that are obtained by amplifying the magnitudes of the plurality of sub-signals S_sub1 and S_sub2. The separator circuit 100 may adjust at least one of amplitudes and phases of the plurality of sub-signals S_sub1 and S_sub2 such that the amplitudes and the phases thereof conform to the characteristics of the directional coupler, and thus, the signal amplification device 10 may restore the shape of the input signal S_in such that the shape of the output signal S_out becomes the shape of the input signal S_in. As will be described below with reference to FIG. 4, the magnitude of the amplitude of the output signal S_out may be proportional to sin²θ of the magnitude of the output power of the amplifiers (see 101 and 102 of FIG. 1), and the shape of the output signal S_out may have the shape of the input signal S_in.

The separator circuit 100 may adjust at least one of amplitudes and phases of the plurality of sub-signals S_sub1 and S_sub2 such that the amplitudes and the phases thereof conform to the characteristics of the directional coupler. Thus, the amplification efficiency of the signal amplification device may become equal to or greater than a threshold. In this case, the threshold represents the amplification efficiency for amplifying an input signal such that data can be transmitted at a speed equal to or higher than a certain value even under back-off conditions.

For example, the separator circuit 100 may adjust the amplitudes of the plurality of sub-signals S_sub1 and S_sub2 to be equal in magnitude to each other. In another example, the separator circuit 100 may adjust the phase of each of the plurality of sub-signals S_sub1 and S_sub2 by adding or subtracting different phase components to or from the phase of the input signal S_in.

The input signal S_in received by the separator circuit 100 may be expressed by Equation 1.

S_in=A(t)cos[ωt+Ø(t)]=Aₘₐₓ sin θ(t)cos[ωt+Ø(t)] [Equation 1]

A represents the amplitude of the input signal S_in, Ø represents the phase of the input signal S_in, Amax represents the maximum value of the magnitude of the amplitude of the input signal S_in, and θ represents the outphasing angle.

The plurality of sub-signals S_sub1 and S_sub2 (which may be referred to as the first sub-signal S_sub1 and the second sub-signal S_sub2, respectively) output by the separator circuit 100 may be expressed by Equation 2.

S_sub1=B_1*sin[ωt+Ø(t)+θ₁(t)]

S_sub2=B_2*sin[ωt+Ø(t)+θ₂(t)] [Equation 2]

B_1 represents the magnitude of the amplitude of the first sub-signal S_sub1, and B_2 represents the magnitude of the amplitude of the second sub-signal S_sub2. In this case, B_1 may be set to conform to the characteristics of the directional coupler based on the maximum value (Amax) of the amplitude of the input signal S_in. In this case, B_2 may be set to conform to the characteristics of the directional coupler based on the maximum value (Amax) of the amplitude of the input signal S_in. A first phase (θ₁) represents the value set based on the outphasing angle (θ), and a second phase (θ₂) represents the value set based on the outphasing angle (θ).

The magnitude (B_1) of the amplitude of the first sub-signal S_sub1 and the magnitude (B_2) of the amplitude of the second sub-signal S_sub2 may represent values for ensuring that the amplification efficiency of the respective amplifiers corresponding to the sub-signals becomes greater than or equal to a threshold. For example, the magnitude (B_1) of the amplitude of the first sub-signal S_sub1 and the magnitude (B_2) of the amplitude of the second sub-signal S_sub2 may represent values that enable the output signal S_out to have the shape of the input signal S_in.

The phase of the first sub-signal S_sub1 has a value obtained by adding the first phase (θ₁) to the phase (Ø) of the input signal S_in. The phase of the second sub-signal S_sub2 has a value obtained by adding the second phase (θ₂) to the phase (Ø) of the input signal S_in.

The first phase (θ₁) and the second phase (θ₂) may represent values for adjusting the phases of the plurality of sub-signals S_sub1 and S_sub2 to conform to the characteristics of the directional coupler and may enable the signal amplification device 10 to increase the amplification efficiency. For example, the first phase (θ₁) may represent a value that is added to the phase (Ø) of the input signal S_in to enable the first amplifier 101 to operate at the amplification efficiency having a threshold value or higher, and the second phase (θ₂) may represent a value that is added to the phase (Ø) of the input signal S_in to enable the second amplifier 102 to operate at an amplification efficiency having a threshold value or higher. The first phase (θ₁) and the second phase (θ₂) may represent values set such that the shape of the output signal S_out of the signal amplification device 10 becomes the shape of the input signal S_in.

For example, the first phase (θ₁) and the second phase (θ₂) may have the same magnitude and opposite sign. In another example, the first phase (θ₁) may have a value of θ-π obtained by subtracting π from the positive outphasing angle (θ), and the second phase (θ₂) may have the negative outphasing angle (−θ). In another example, the first phase (θ₁) and the second phase (θ₂) may be set such that the phase of the first sub-signal S_sub1 and the phase of the second sub-signal S_sub2 have the same magnitude and opposite sign.

The first amplifier 101 may be configured to receive the first sub-signal S_sub1 and amplify the power of the first sub-signal S_sub1 to generate the amplified signal S_amp1 (which may be referred to as the first amplified signal S_amp1). The first amplifier 101 may be supplied with a preset direct current (DC) voltage as a bias voltage. The first amplifier 101 may output the first amplified signal S_amp1 to the directional coupler 103.

The first amplifier 101 may be a class B amplifier including a transistor having a gate end that receives the first sub-signal S_sub1, a source end that is grounded, and a drain end that outputs the first amplified signal S_amp1. Here, the transistor may include an n-channel metal-oxide semiconductor (NMOS) transistor or a p-channel metal-oxide semiconductor (PMOS) transistor. Here, the class B amplifier may also be supplied with the bias voltage via the drain end. In some embodiments, the first amplifier 101 may include multiple transistors, and may include one or more NMOS transistors and/or one or more PMOS transistors.

The class B amplifier represents an amplifier that is biased to operate for half a cycle of the signal received by the amplifier and to turn off for the other half of the cycle. A class A amplifier represents an amplifier that is biased to operate for the full cycle of the signal received by the amplifier. The class B amplifier draws no DC power because no current flows when there is no reception signal. Therefore, the class B amplifier has higher power amplification efficiency than the class A amplifier. By implementing the class B amplifier, amplification efficiency may be further increased. The second amplifier 102 may be configured to receive the second sub-signal S_sub2 and amplify the power of the second sub-signal S_sub2 to generate the amplified signal S_amp2 (which may be referred to as the second amplified signal S_amp2). The second amplifier 102 may be supplied with a preset DC voltage as a bias voltage. The second amplifier 102 may output the second amplified signal S_amp2 to the directional coupler 103.

The second amplifier 102 may be a class B amplifier including a transistor having a gate end that receives the second sub-signal S_sub2, a source end that is grounded, and a drain end that outputs the second amplified signal S_amp2. Here, the transistor may include an NMOS transistor or a PMOS transistor. In some embodiments, the second amplifier 102 may include multiple transistors, and may include one or more NMOS transistors and/or one or more PMOS transistors.

The directional coupler 103 may be configured to receive the first amplified signal S_amp1 and the second amplified signal S_amp2 and couple those amplified signals to each other based on characteristics of the directional coupler 103 to generate the output signal S_out.

The directional coupler 103 may include a four-port directional coupler. In the signal amplification device 10, the first amplified signal S_amp1 and the second amplified signal S_amp2 may be received via a coupled port COU_P and a through port THR_P of the directional coupler 103, respectively.

The directional coupler 103 may couple the first amplified signal S_amp1 and the second amplified signal S_amp2 to each other based on the characteristics of the directional coupler. For example, based on a phase difference between the coupled port COU_P and the through port THR_P being 90°, the first amplified signal S_amp1 and the second amplified signal S_amp2 may be coupled to each other.

In order to reduce reflections and losses in the signal and transmit maximum power, the impedance may be matched. Among methods of matching impedance, quarter-wave impedance matching (λ/4 matching) represents a method of matching impedance in radio frequency (RF) and microwave circuits by matching the length of a transmission line to one-fourth the wavelength (λ) of the signal. The length of the directional coupler 103 may be configured such that impedance matching is achieved. The length of the internal transmission line of the directional coupler 103 may be configured such that impedance matching is achieved.

The signal amplification device 10 may achieve impedance matching by coupling the first amplified signal S_amp1 and the second amplified signal S_amp2 to each other via the directional coupler 103 that includes λ/4 lengths of transmission lines. As the impedance matching is made, the signal amplification device 10 may reduce power losses due to reflections and losses of the signal and thus transmit high power. Accordingly, the amplification efficiency of the signal amplification device 10 may be increased.

The signal amplification device 10 may be configured such that impedance is connected to an isolated port ISO_P of the directional coupler 103. In this case, the type of impedance that may be connected to the isolated port ISO_P of the directional coupler 103 may include a capacitor 104. In order to prevent reflection and loss of the signal and improve the isolation performance, the magnitude of reactance of the capacitor 104 may be the same as the magnitude of the characteristic impedance (Z0) of the directional coupler 103.

When a resistor is connected to the isolated port ISO_P of the directional coupler 103, power loss may occur due to heat generated by the resistor. As the signal amplification device 10 is configured such that the capacitor 104 is connected to the isolated port ISO_P of the directional coupler 103, power loss due to heat generation may be reduced. Accordingly, the signal amplification device 10 may transmit high power, and the amplification efficiency thereof may be increased. Therefore, as the capacitor 104 is connected to the isolated port ISO_P of the directional coupler 103, the amplifiers (101, 102) may operate at high efficiency even under a back-off condition.

The signal amplification device 10 may output the output signal S_out, in which the plurality of amplified signals S_amp1 and S_amp2 are coupled to each other, via an input port IN_P of the directional coupler 103. The signal amplification device 10 may output the output signal S_out in which the shape of the input signal S_in is restored, as shown in Equation 3.

S_out=C(t)cos[ωt+Ø(t)+k] [Equation 3]

k represents the phase difference between the input signal S_in and the output signal S_out, and C represents the magnitude of the output signal S_out. The magnitude of the output signal S_out may be determined based on the gain of the amplifier, the efficiency of the amplifier, or the outphasing angle.

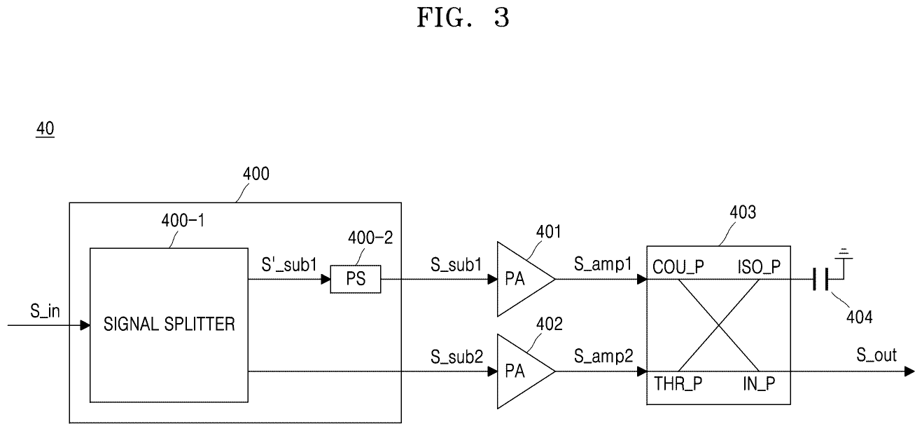

FIG. 3 is a diagram showing a configuration of a signal amplification device 40 according to another embodiment. Hereinafter, a process by which a signal amplification device restores the shape of an input signal is described using equations.

The signal amplification device 40 according to another embodiment may include a separator circuit 400, a first amplifier 401, a second amplifier 402, a directional coupler 403, and a capacitor 404. All of the blocks illustrated in FIG. 3 are not required components. In another embodiment, some of the blocks in FIG. 3 may be changed or deleted, and other blocks may be added thereto.

The separator circuit 400 may include a signal splitter (e.g., signal splitter circuit) 400-1 and a phase shifter (e.g., phase shifter circuit) 400-2. The separator circuit 400 may adjust the amplitude or phase of the input signal S_in such that the input signal S_in conforms to the characteristics of the directional coupler 403, and may generate the first sub-signal S_sub1 and the second sub-signal S_sub2.

The signal splitter 400-1 may receive the input signal S_in and adjust the amplitude or phase of the input signal S_in to split the input signal S_in into a first preliminary sub-signal S′_sub1 and the second sub-signal S_sub2.

The signal splitter 400-1 may adjust the phase or amplitude of the first preliminary sub-signal S′_sub1 such that the first amplifier 401 achieves the amplification efficiency greater than or equal to a threshold. The signal splitter 400-1 may adjust the phase or amplitude of the second sub-signal S_sub2 such that the second amplifier 402 achieves the amplification efficiency greater than or equal to a threshold.

The input signal S_in may be expressed by Equation 1. The first preliminary sub-signal S′_sub1 and the second sub-signal S_sub2 may be expressed by Equation 4.

$${S}^{′} \_sub1 = \frac{{A}_{max}}{2} sin [ ω t + ϕ ( t ) + θ ( t ) ] \qquad [ Equation 4 ]$$

$${S}^{′} \_sub2 = \frac{{A}_{max}}{2} sin [ ω t + ϕ ( t ) + θ ( t ) ]$$

The signal splitter 400-1 may set the phase of the first preliminary sub-signal S′_sub1 by adding a positive outphasing angle (θ) to the phase of the input signal S_in. The signal splitter 400-1 may set the phase of the second sub-signal S_sub2 by adding a negative outphasing angle (−θ) to the phase of the input signal S_in.

The phase shifter 400-2 may receive the first preliminary sub-signal S′_sub1 from the signal splitter 400-1 and output the first sub-signal S_sub1, which is generated by shifting the phase of the first preliminary sub-signal S′_sub1, to the first amplifier 401.

The phase shifter 400-2 may adjust the phase of the first sub-signal S_sub1 to conform to the characteristics of the directional coupler 403. For example, the phase shifter 400-2 may shift the phase of the first preliminary sub-signal S′_sub1 by considering a phase difference between the through port and the coupled port of the directional coupler. The phase shifter 400-2 may set the phase of the first sub-signal S_sub1 by shifting the phase of the first preliminary sub-signal S′_sub1 by 180°.

The first amplifier 401 may receive the first sub-signal S_sub1 from the phase shifter 400-2, and may amplify the magnitude of the power of the first sub-signal S_sub1 to output the first amplified signal S_amp1. The first amplifier 401 may be supplied with a preset DC voltage as a bias voltage. The first amplifier 401 may have the structure of the class B amplifier as described above. The voltage (V_1) of the first amplified signal S_amp1 output by the first amplifier 401 may be expressed by Equation 5.

V_1=Vᵢe^{j(θ-π)} [Equation 5]

Vᵢ is the phaser representation including the phase components of the input signal S_in.

The second amplifier 402 may receive the second sub-signal S_sub2 from the separator circuit 400, and may output the second amplified signal S_amp2 generated by amplifying the magnitude of the power of the second sub-signal S_sub2. The second amplifier 402 may be supplied with a preset DC voltage as a bias voltage. The second amplifier 402 may have the structure of the class B amplifier as described above. The voltage (V_2) of the second amplified signal S_amp2 output by the second amplifier 402 may be expressed by Equation 6.

V_2=Vᵢe^{-jθ} [Equation 6]

Vᵢ is the phaser representation including the phase components of the input signal S_in.

FIG. 4 is a diagram showing the structure of a directional coupler 403 according to an embodiment.

The directional coupler 403 may be configured as a four-port directional coupler that includes two transmission lines 403-1 and 403-2 having a coupling coefficient (c). The length of the directional coupler 403 may be λ/4, and may thereby have λ/4 matching. Each of the two internal transmission lines 403-1 and 403-2 of the directional coupler 403 may have a length of λ/4.

The even mode impedance (Z₀ₑ) and the odd mode impedance (Z₀ₒ) of the directional coupler 403 may be expressed by Equation 7.

$${Z}_{0 e} = {Z}_{0} \sqrt{\frac{1 + c}{1 - c}} \qquad [ Equation 7 ]$$

$${Z}_{0 o} = {Z}_{0} \sqrt{\frac{1 - c}{1 + c}}$$

Z₀ represents the characteristic impedance of the directional coupler.

The directional coupler 403 may receive the first amplified signal S_amp1 from the first amplifier 401 via the coupled port COU_P. The directional coupler 403 may receive the second amplified signal S_amp2 from the second amplifier 402 via the through port THR_P.

The directional coupler 403 may couple a first amplified signal S′_amp1 and the second amplified signal S_amp2 to each other to generate the output signal S_out based on the characteristics of the directional coupler 403, and may output the output signal S_out via the input port IN_P.

The phase difference between the ports of the directional coupler 403 may be set based on characteristics of the directional coupler 403. For example, the difference between the phase of the input port IN_P and the phase of the coupled port COU_P may be set to 90° so that the amplification efficiency of the signal amplification device is greater than or equal to a threshold.

Impedance may be connected to the isolated port ISO_P of the directional coupler 403. The impedance connected to the isolated port ISO_P of the directional coupler 403 may be the capacitor 404. The magnitude of the reactance of the capacitor 404 may be equal to the magnitude of the characteristic impedance (Zo) of the directional coupler 403.

When the even mode impedance (Z₀ₑ) of the directional coupler 403 is 120.71Ω, the odd mode impedance (Z₀ₒ) is 20.71Ω, and the difference between the phase of the through port THR_P and the phase of the coupled port COU_P at the center frequency is 90°, the current-voltage relationship may be expressed as shown in Equation 8 by using the four-port impedance matrix of the directional coupler. In this case, the center frequency represents the frequency at which the directional coupler operates at optimal performance. In this case, the four-port impedance matrix of the directional coupler reflects the characteristics of the directional coupler.

$$[ \begin{matrix}- I\_L \\ I\_ 1 \\ I\_ 2 \\ - I\_ISO\end{matrix} ] = \frac{1}{{Z}_{o}} [ \begin{matrix}0 & 0 & j \sqrt{2} & - j \\ 0 & 0 & - j & j \sqrt{2} \\ j \sqrt{2} & - j & 0 & 0 \\ - j & j \sqrt{2} & 0 & 0\end{matrix} ] [ \begin{matrix}V\_L \\ {V}_{i} {e}^{j ( θ - π )} \\ {V}_{i} {e}^{- j θ} \\ V\_ISO\end{matrix} ] . \qquad [ Equation 8 ]$$

I_L represents the current output from the input port IN_P of the directional coupler 403, I_1 represents the current input to the coupled port COU_P of the directional coupler, I_2 represents the current input to the through port THR_P of the directional coupler, I_ISO represents the current output from the isolated port ISO_P of the directional coupler, Z₀ represents the characteristic impedance of the directional coupler, V_L represents the output voltage at a load, and V_ISO represents the voltage of impedance (e.g., a capacitor) connected to the isolated port ISO_P of the directional coupler. Vᵢ is the phaser representation including the phase components of the input signal S_in.

Referring to Equation 8, the output voltage (V_L) at the load may be expressed as shown in Equation 9.

$$V\_L = 2 {V}_{i} {e}^{- j \frac{3}{4} π} sin θ \qquad [ Equation 9 ]$$

Referring to Equation 3 and Equation 9, the output signal S_out of the directional coupler 403 is restored in the form of the input signal S_in, and the magnitude of the output signal S_out is proportional to sin²θ of the output power of the first and second amplifiers 401 and 402 (which may be referred to as the amplifiers 401 and 402).

Referring to Equation 8, equivalent admittance (Y_1) when the first amplified signal S′_amp1 is transmitted from the first amplifier 401 to the directional coupler 403 and equivalent admittance (Y_2) when the second amplified signal S_amp2 is transmitted from the second amplifier 402 to the directional coupler 403 may be expressed by Equation 10.

$$Y\_ 1 = \frac{I\_ 1}{V\_ 1} = \frac{2 {sin}^{2} θ + j [ sin ( 2 θ ) - 1 ]}{R\_L} \qquad [ Equation 10 ]$$

$$Y\_ 2 = \frac{I\_ 2}{V\_ 2} = \frac{2 {sin}^{2} θ - j [ sin ( 2 θ ) - 1 ]}{R\_L} .$$

In order to transmit power without loss of signal, the equivalent parallel conductance has to decrease in the back-off condition.

Referring to Equation 10, the equivalent parallel conductance (Gₚ₁) when the first amplified signal S′_amp1 is transmitted from the first amplifier 401 to the directional coupler 403 and the equivalent parallel conductance (Gₚ₂) when the second amplified signal S_amp2 is transmitted from the second amplifier 402 to the directional coupler 403 may be expressed by Equation 11.

$${G}_{p 1} = Re ( Y\_ 1 ) = \frac{2 {sin}^{2} θ}{R\_L} \qquad [ Equation 11 ]$$

$${G}_{p2} = Re ( Y\_ 2 ) = \frac{2 {sin}^{2} θ}{R\_L} .$$

Referring to Equation 11, the signal amplification device 40 may reduce losses in the signal by lowering the equivalent parallel conductance (Gₚ₁ and Gₚ₂) based on the outphasing angle (θ). The signal amplification device 40 may also operate as a non-isolated coupler capable of transmitting signals without power loss in an active load modulation method based on the outphasing angle (θ). Therefore, in a wireless transmission system, the signal amplification device 40 may optimize the amplification efficiency and linearity of the amplifiers 401 and 402 even under back-off conditions.

Referring to Equation 10, the equivalent parallel susceptance (Bₚ₁) when the first amplified signal S_amp1 is transmitted from the first amplifier 401 to the directional coupler 403 and the equivalent parallel susceptance (Bₚ₂) when the second amplified signal S_amp2 is transmitted from the second amplifier 402 to the directional coupler 403 may be expressed by Equation 12.

$${B}_{p 1} = Imag ( Y\_ 1 ) = \frac{sin 2 θ - 1}{R\_L} \qquad [ Equation 12 ]$$

$${B}_{p2} = Imag ( Y\_ 2 ) = \frac{sin 2 θ - 1}{R\_L}$$

Referring to Equation 12, when the outphasing angle is 45°, the magnitudes of the equivalent parallel susceptance (Bₚ₁ and Bₚ₂) are minimized. Accordingly, the signal amplification device 40 may improve power transfer efficiency, minimize losses due to reflections, and improve linearity.

When the first amplifier 401 and the second amplifier 402 are class B amplifiers, the efficiency (η₁ and η₂) of the amplifiers may be expressed by Equation 13.

$${η}_{1} = \frac{{P}_{RF 1}}{{P}_{DC 1}} = \frac{π}{4} \frac{{G}_{p 1}}{\sqrt{{G}_{p 1}^{2} + {B}_{p 1}^{2}}} \qquad [ Equation 13 ]$$

$${η}_{2} = \frac{{P}_{RF 2}}{{P}_{DC 2}} = \frac{π}{4} \frac{{G}_{p 2}}{\sqrt{{G}_{p 2}^{2} + {B}_{p2}^{2}}} .$$

P_{RF1} represents the output power of the first amplifier 401, P_{DC1} represents the bias power of the first amplifier 401, P_{RF2} represents the output power of the second amplifier 402, and P_{DC2} represents the bias power of the second amplifier 402.

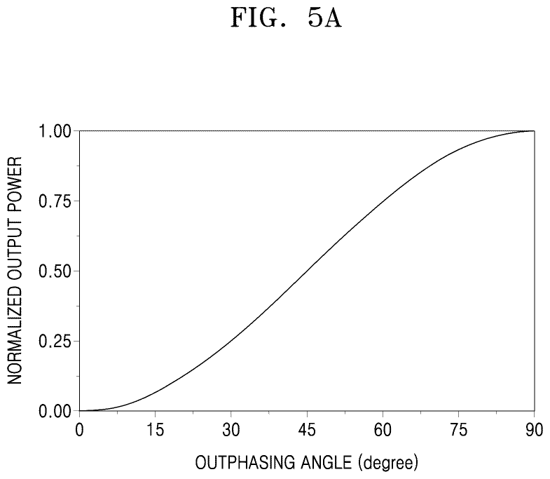

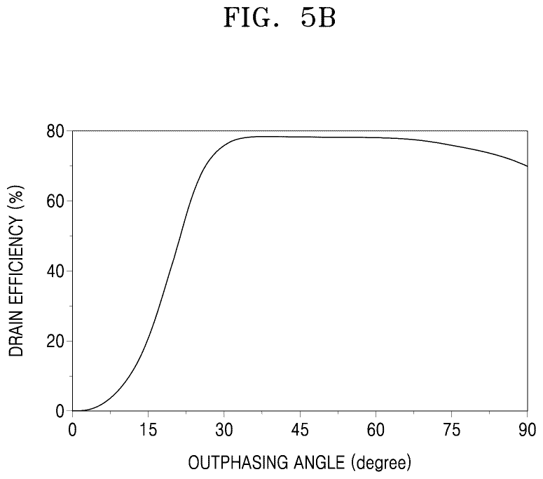

FIGS. 5A and 5B are diagrams illustrating an operation of an amplifier based on an outphasing angle, according to an embodiment. FIG. 5A is a graph showing the relationship between the outphasing angle and the output power of the amplifier, and FIG. 5B is a graph showing the relationship between the outphasing angle and the amplification efficiency of the amplifier.

Referring to FIG. 5A, the signal amplification device 40 outputs the output signal S_out restored in the form of the input signal S_in, and the magnitude of the output signal S_out is proportional to sin² of the magnitudes of the output power of the first amplifier 401 and the second amplifier 402.

Referring to FIG. 5B and Equation 13, when the first amplifier 401 and the second amplifier 402 are class B amplifiers and the outphasing angle is 45°, the magnitudes of the equivalent parallel susceptance (Bₚ₁ and Bₚ₂) are minimized, and thus, the amplifiers 401 and 402 may operate at maximum efficiency of about 78.5% under the back-off condition.

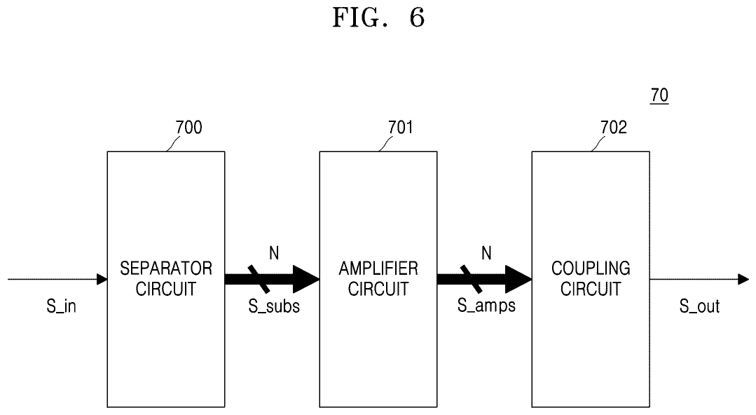

FIG. 6 is a diagram showing a configuration of a signal amplification device 70 according to another embodiment.

The signal amplification device 70 according to an embodiment may include a separator circuit 700, an amplifier circuit 701, and a coupling circuit 702. All of the blocks illustrated in FIG. 6 are not required components. In another embodiment, some of the blocks in FIG. 6 may be changed or deleted, and other blocks may be added thereto.

The separator circuit 700 may be configured to receive the input signal S_in, separate the input signal S_in into a plurality of sub-signals S_subs, and output the same. The separator circuit 700 may be configured to separate the input signal S_in into the plurality of sub-signals S_subs such that the phase or amplitude of the input signal S_in is adjusted to conform to the characteristics of a directional coupler. The plurality of sub-signals S_subs may be signals of which the phase or amplitude is adjusted such that the amplification efficiency of the signal amplification device 70 is greater than or equal to a threshold. Because the output signal S_out is generated by coupling the signals, which are obtained by amplifying the magnitudes of the plurality of sub-signals S_subs, the plurality of sub-signals S_subs may be adjusted such that the output signal S_out has the same shape as the input signal S_in. The separator circuit 700 may set the magnitude of the amplitude of each sub-signal by adjusting the amplitude of the input signal S_in to a preset magnitude, and may set the phase of each sub-signal by adding or subtracting different phase components to or from the phase of the input signal S_in.

The amplifier circuit 701 may receive the plurality of sub-signals S_subs from the separator circuit 700, amplify the power of the plurality of sub-signals S_subs, and output a plurality of amplified signals S_amps that are the amplified signals. The amplifier circuit 701 may include a plurality of amplifiers respectively corresponding to the plurality of sub-signals S_subs. The plurality of amplifiers may include class B amplifiers.

The coupling circuit 702 may include a directional coupler.

The coupling circuit 702 may be configured to receive the plurality of amplified signals S_amps from the amplifier circuit 701, couple the plurality of amplified signals S_amps based on the characteristics of the directional coupler to generate the output signal S_out, and output the output signal S_out. The characteristics of the directional coupler may include characteristic impedance, even mode impedance (Z₀ₑ), odd mode impedance (Z₀ₒ), and a phase difference between a plurality of first ports.

The directional coupler may include the plurality of first ports which respectively correspond to the plurality of amplified signals S_amps and respectively receive the amplified signals S_amps, a second port which outputs the output signal, and a third port to which the impedance is connected.

The type of impedance connected to the third port of the directional coupler may include a capacitor. The magnitude of the reactance of the capacitor connected to the third port of the directional coupler may be equal to the characteristic impedance of the directional coupler.

The coupling circuit 702 may be configured to satisfy an impedance matching condition. The internal transmission lines of the coupling circuit 702 may each have a length of λ/4.

The output signal S_out may have the shape of the input signal S_in and have an amplified magnitude greater than the magnitude of the input signal S_in. That is, the signal amplification device 70 may output the amplified signal while restoring the shape of the original signal.

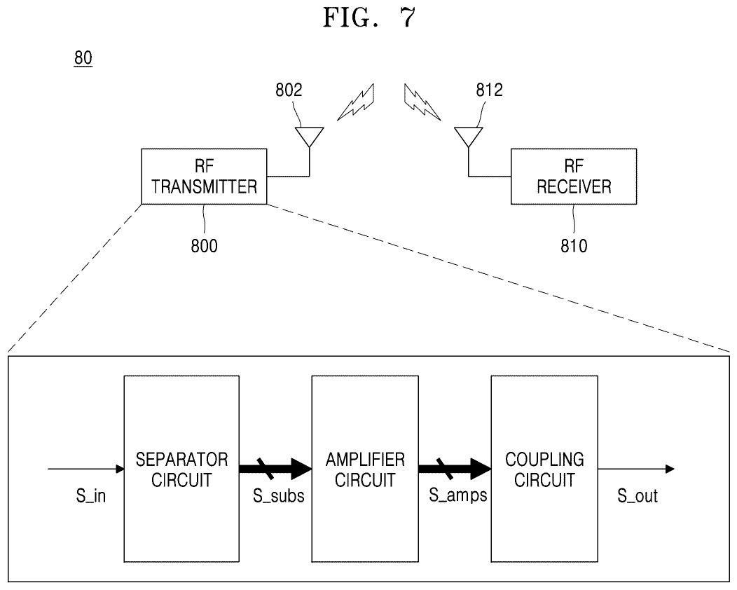

FIG. 7 is a diagram showing a configuration of an electronic apparatus 80 in which a signal amplification device according to an embodiment is formed.

Referring to FIG. 7, the electronic apparatus 80 may include an RF transmitter 800 and an RF receiver 810. The electronic apparatus 80 may transmit (or radiate) a signal via the RF transmitter 800 and receive the signal via the RF receiver 810.

In the case of uplink communication, the RF transmitter 800 corresponds to a transmitter of a terminal, and the RF receiver 810 corresponds to a receiver of a base station. In the case of downlink communication, the RF transmitter 800 corresponds to a transmitter of a base station, and the RF receiver 810 corresponds to a receiver of a terminal. The terminal may include a user device capable of performing communication functions (e.g., transmission and reception). For example, the terminal may include user equipment (UE), a mobile station (MS), a wireless transmit/receive unit (WTRU), a cellular phone, a smartphone, a machine-type communication (MTC) device, a computer, a wireless sensor, a vehicle, an Internet of Things (IoT) device, and/or other electronic apparatuses capable of performing communication functions. The terminal may communicate with other terminals or communicate with one or more network nodes in a wireless access network. The base station as a unit of performing the resource allocation of the terminal may include a radio base station, a NodeB, an evolved Node B (eNodeB or eNB), a next generation Node B (gNodeB or gNB), a wireless access unit, a network node, a network device, a node on a network, a base station controller, a transmission point (TP), an access point (AP), a relay station, a base band unit (BBU), a remote radio unit (RRU), a central unit (CU), at least one distribute unit (DU) controlled/managed by the CU, a remote radio head (RRH), or a transmit and receive point (TRP).

The RF transmitter 800 may include the signal amplification devices described above and an antenna 802. For example, the RF transmitter 800 may receive an RF signal as an input signal via the signal amplification device, amplify the power of the RF signal based on an outphasing method, and radiate the amplified signal into the air via an antenna.

The RF receiver 810 may include, but is not limited to, a low noise amplifier (LNA) and an antenna 812. According to an embodiment, the RF receiver 810 may utilize the LNA to process the signal received via the antenna 812.

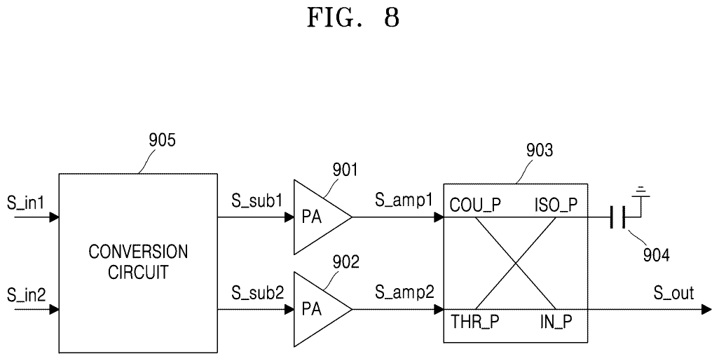

FIG. 8 is a diagram showing a configuration of a signal amplification device 90 according to an embodiment.

The signal amplification device 90 according to an embodiment may include a conversion circuit 905, a first amplifier 901, a second amplifier 902, a directional coupler 903, and a capacitor 904.

The conversion circuit 905 may be configured to convert a first input signal S_in1 to generate the first sub-signal S_sub1 and output the first sub-signal S_sub1. The conversion circuit 905 may adjust the phase or amplitude of the first input signal S_in1 to conform to the characteristics of the directional coupler 903, thereby generating the first sub-signal S_sub1. The first input signal S_in1 and a second input signal S_in2 may have the same phase component.

The conversion circuit 905 may be configured to convert the second input signal S_in2 to generate the second sub-signal S_sub2 and output the second sub-signal S_sub2. The conversion circuit 905 may adjust the phase or amplitude of the second input signal S_in2 to conform to the characteristics of the directional coupler 903, thereby generating the second sub-signal S_sub2.

The first sub-signal S_sub1 and the second sub-signal S_sub2 may have the same amplitude. The phase of the first sub-signal S_sub1 may be θ-π and the phase of the second sub-signal S_sub2 may be −θ.

The first amplifier 901 may be configured to receive the first sub-signal S_sub1 from the conversion circuit 905, amplify the power of the first sub-signal S_sub1 to generate the first amplified signal S_amp1, and output the first amplified signal S_amp1. The first amplifier 901 may be supplied with a preset DC voltage as a bias voltage. The first amplifier 901 may have the structure of the class B amplifier as described above.

The second amplifier 902 may be configured to receive the second sub-signal S_sub2 from the conversion circuit 905, amplify the power of the second sub-signal S_sub2 to generate the second amplified signal S_amp2, and output the second amplified signal S_amp2. The second amplifier 902 may be supplied with a preset DC voltage as a bias voltage. The second amplifier 902 may have the structure of the class B amplifier as described above.

The directional coupler 903 may be formed as a four-port directional coupler including two transmission lines. The length of the directional coupler 903 may be λ/4, and may thereby have λ/4 matching. Each of the two internal transmission lines of the directional coupler 903 may have a length of λ/4. As the impedance matching is performed, power losses due to reflections and losses in the signal may decrease. As a result, the signal amplification device 90 may transmit high power. As the impedance matching is achieved, the amplification efficiency of the first and second amplifiers 901 and 902 may increase. Consequently, the first and second amplifiers 901 and 902 may operate at high efficiency even under back-off conditions.

The directional coupler 903 may receive the first amplified signal S_amp1 from the first amplifier 901 via the coupled port COU_P. The directional coupler 903 may receive the second amplified signal S_amp2 from the second amplifier 902 via the through port THR_P.

Impedance may be connected to the isolated port ISO_P of the directional coupler 903. The impedance connected to the isolated port ISO_P of the directional coupler 903 may be the capacitor 904. The magnitude of the reactance of the capacitor 904 may be equal to the magnitude of the characteristic impedance (Z₀) of the directional coupler 903. As the capacitor 904 is connected to the isolated port ISO_P of the directional coupler 903, power losses due to heat generation may be reduced. Accordingly, the first amplifier 901 and the second amplifier 902 may operate at high efficiency even under back-off conditions.

The directional coupler 903 may generate the output signal S_out by coupling the first amplified signal S_amp1 and the second amplified signal S_amp2 to each other based on the characteristics of the directional coupler 903. The directional coupler 903 may output the output signal S_out via the input port IN_P. The output signal S_out may be a signal having the restored shape of the first input signal S_in1 or the restored shape of the second input signal S_in2.

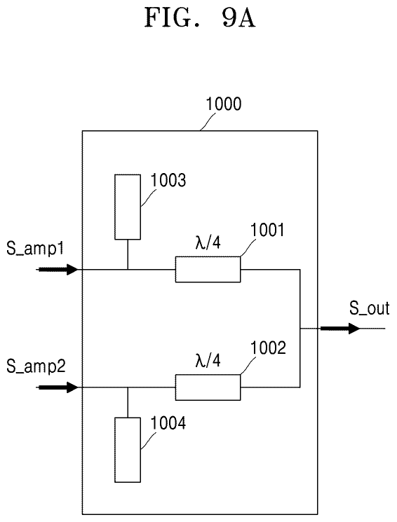

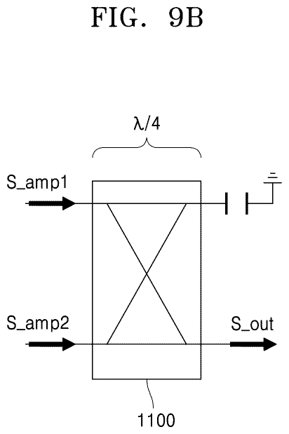

FIGS. 9A and 9B are diagrams comparing the degrees of integration between devices according to an embodiment and devices according to a comparative example. FIG. 9A is a diagram illustrating a coupling unit of an outphasing combiner according to the comparative example. FIG. 9B is a diagram illustrating a coupling unit according to an embodiment.

Referring to FIG. 9A, a coupling unit 1000 of the outphasing combiner according to the comparative example may have an outphasing architecture that includes two transmission lines 1001 and 1002 and two open stubs 1003 and 1004. In order to minimize power losses and increase the amplification efficiency of the amplifier, the two transmission lines 1001 and 1002 may have an electrical length of λ/4. However, in the coupling unit 1000, two open stubs 1003 and 1004 are required to be connected to the two transmission lines 1001 and 1002, respectively, to compensate for parallel reactance.

Referring to FIG. 9B, a coupling unit 1100 of devices according to an embodiment may have an outphasing architecture that includes a directional coupler. The directional coupler may include internal transmission lines having a coupling coefficient. The internal transmission lines may have an electrical length of 14 and may thereby minimize power losses and increase the amplification efficiency of the amplifier. Therefore, the coupling unit 1100 of the devices according to an embodiment may have fewer parallel reactance elements than the coupling unit 1000 of the outphasing combiner according to the comparative example. Therefore, the coupling unit 1100 of the devices according to an embodiment may reduce the chip area when integrated, compared to the coupling unit 1000 of the outphasing combiner according to the comparative example, and may thus increase the degree of integration.

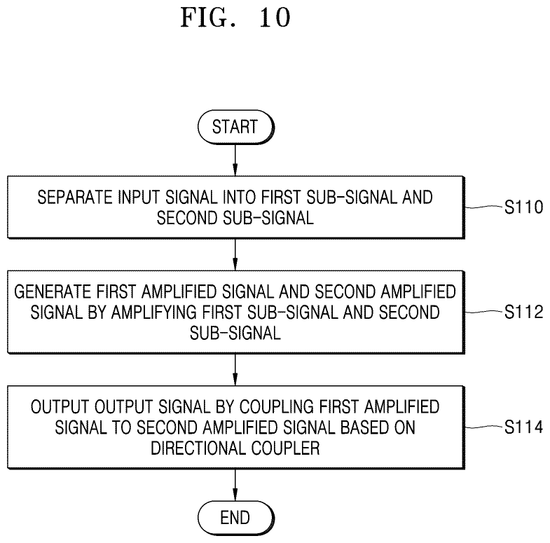

FIG. 10 is a flowchart illustrating a signal amplification method according to an embodiment.

In operation S110, the signal amplification method according to an embodiment may include separating an input signal into a first sub-signal and a second sub-signal by adjusting the amplitude or phase of the input signal. The amplitude of the first sub-signal may have the same magnitude as the amplitude of the second sub-signal. The phase of the first sub-signal and the phase of the second sub-signal may be set by adding different phase components to or subtracting different phase components from the phase of the input signal.

In operation S112, the signal amplification method may include generating a first amplified signal by amplifying power of the first sub-signal using a first amplifier corresponding to the first sub-signal, and generating a second amplified signal by amplifying power of the second sub-signal using a second amplifier corresponding to the second sub-signal.

In operation S114, the signal amplification method may include generating an output signal by coupling the first amplified signal and the second amplified signal to each other using a directional coupler based on characteristics of the directional coupler. The signal amplification method may include outputting the output signal via an input port of the directional coupler. A capacitor may be connected to an isolated port of the directional coupler. The reactance of the capacitor may have the same magnitude as the characteristic impedance of the directional coupler. The signal amplification method may include inputting the first amplified signal and the second amplified signal to a through port and a coupled port of the directional coupler. The output signal may be a signal having the restored shape of the input signal.

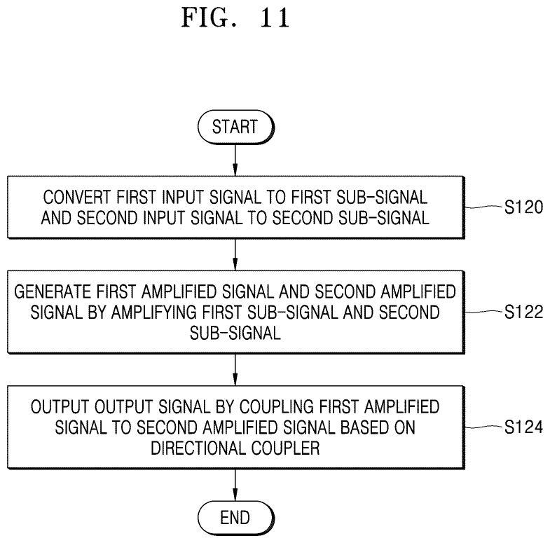

FIG. 11 is a flowchart illustrating a signal amplification method according to an embodiment.

In operation S120, the signal amplification method according to an embodiment may include generating a first sub-signal by adjusting an amplitude or phase of a first input signal, and generating a second sub-signal by adjusting an amplitude or phase of a second input signal.

The phases of the first input signal may have the same components as the phase of the second input signal. The amplitude of the first sub-signal may have the same magnitude as the amplitude of the second sub-signal. The phase of the first sub-signal and the phase of the second sub-signal may each be set by adding different phase components to or subtracting different phase components from the phase of the input signal.

In operation S122, the signal amplification method may include generating a first amplified signal by amplifying power of the first sub-signal using a first amplifier corresponding to the first sub-signal, and generating a second amplified signal by amplifying power of the second sub-signal using a second amplifier corresponding to the second sub-signal.

In operation S124, the signal amplification method may include generating an output signal by coupling the first amplified signal and the second amplified signal to each other using a directional coupler based on characteristics of the directional coupler. The signal amplification method may include outputting the output signal via an input port of the directional coupler. A capacitor may be connected to an isolated port of the directional coupler. The reactance of the capacitor may have the same magnitude as the characteristic impedance of the directional coupler. The signal amplification method may include coupling the first amplified signal and the second amplified signal to each other by inputting the first amplified signal and the second amplified signal to a through port and a coupled port of the directional coupler.

While aspects of embodiments have been particularly shown and described, it will be understood that various changes in form and details may be made therein without departing from the spirit and scope of the following claims.

What is claimed is:

1. A signal amplification device comprising:
a separator circuit configured to separate an input signal into a first sub-signal and a second sub-signal;
a first amplifier configured to amplify the first sub-signal, and output a first amplified signal;
a second amplifier configured to amplify the second sub-signal, and output a second amplified signal;
a directional coupler; and
a capacitor connected to an isolated port of the directional coupler,
wherein the directional coupler is configured to:
receive the first amplified signal via a coupled port of the directional coupler;
receive the second amplified signal via a through port of the directional coupler; and
output an output signal generated by coupling the first amplified signal to the second amplified signal via an input port of the directional coupler.

2. The signal amplification device of claim 1, wherein the separator circuit is further configured to adjust an amplitude or a phase of the input signal to separate the input signal into the first sub-signal and the second sub-signal, and
wherein each of the first sub-signal and the second sub-signal has an amplitude or a phase conforming to characteristics of the directional coupler.

3. The signal amplification device of claim 2, wherein the characteristics of the directional coupler comprise any one or any combination of characteristic impedance of the directional coupler, even mode impedance, odd mode impedance, and a phase difference between the through port and the coupled port of the directional coupler.

4. The signal amplification device of claim 1, wherein reactance of the capacitor has a same magnitude as characteristic impedance of the directional coupler.

5. The signal amplification device of claim 2, wherein an amplitude of the first sub-signal has a same magnitude as an amplitude of the second sub-signal,
wherein a phase of the first sub-signal is shifted such that a sum of the phase of the input signal and an outphasing angle conforms to the characteristics of the directional coupler, and
wherein a phase of the second sub-signal represents a difference between the phase of the input signal and the outphasing angle.

6. The signal amplification device of claim 5, wherein the separator circuit comprises a phase shifter circuit configured to shift a phase of the sum of the phase of the input signal and the outphasing angle by a magnitude conforming to the characteristics of the directional coupler.

7. The signal amplification device of claim 5, wherein the separator circuit comprises a phase shifter circuit configured to shift a phase of the sum of the phase of the input signal and the outphasing angle by 180°.

8. The signal amplification device of claim 1, wherein each of the first amplifier and the second amplifier comprises a class B amplifier.

9. The signal amplification device of claim 5, wherein a phase difference between the through port and the coupled port of the directional coupler is 90°.

10. The signal amplification device of claim 1, wherein the directional coupler comprises a transmission line having a length of λ/4 (where λ is a wavelength of the input signal).

11. An electronic apparatus comprising a radio frequency (RF) transmitter,
wherein the RF transmitter comprises:
a separator circuit configured to separate an input signal into a plurality of sub-signals;
an amplifier circuit configured to amplify each of the plurality of sub-signals, and output a plurality of amplified signals;
a coupling circuit comprising a directional coupler configured to couple the plurality of amplified signals to each other to generate an output signal, and output the output signal; and
an antenna configured to transmit the output signal, and
wherein the directional coupler comprises a plurality of first ports configured to receive the plurality of amplified signals, a second port configured to output the output signal, and a third port to which impedance is connected.

12. The electronic apparatus of claim 11, wherein the separator circuit is further configured to adjust an amplitude or a phase of the input signal to separate the input signal into the plurality of sub-signals,
wherein each of the plurality of sub-signals has an amplitude or a phase conforming to characteristics of the directional coupler, and
wherein the characteristics of the directional coupler comprise any one or any combination of characteristic impedance of the directional coupler, even mode impedance, odd mode impedance, and a phase difference between the plurality of first ports.

13. The electronic apparatus of claim 12, wherein the impedance comprises a capacitor.

14. The electronic apparatus of claim 13, wherein reactance of the capacitor has a same magnitude as the characteristic impedance of the directional coupler.

15. The electronic apparatus of claim 12, wherein the coupling circuit comprises a plurality of transmission lines configured to achieve impedance matching.

16. The electronic apparatus of claim 15, wherein each of the plurality of transmission lines has a length of λ/4 (where λ is a wavelength of the input signal).

17. The electronic apparatus of claim 12, wherein the amplifier circuit comprises a plurality of class B amplifiers.

18. A signal amplification device comprising:
a conversion circuit configured to generate a first sub-signal based on a first input signal, and a second sub-signal based on a second input signal;
a first amplifier configured to amplify the first sub-signal, and output a first amplified signal;
a second amplifier configured to amplify the second sub-signal, and output a second amplified signal;
a directional coupler; and
a capacitor connected to an isolated port of the directional coupler,
wherein the directional coupler is configured to:
receive the first amplified signal via a coupled port of the directional coupler;
receive the second amplified signal via a through port of the directional coupler; and
output an output signal generated by coupling the first amplified signal to the second amplified signal via an input port of the directional coupler.

19. The signal amplification device of claim 18, wherein the conversion circuit is further configured to adjust amplitudes or phases of the first input signal and the second input signal to respectively convert the first input signal and the second input signal into the first sub-signal and the second sub-signal having amplitudes or phases conforming to characteristics of the directional coupler, and output the first sub-signal and the second sub-signal, and
wherein the characteristics of the directional coupler comprise any one or any combination of characteristic impedance of the directional coupler, even mode impedance, odd mode impedance, and a phase difference between the through port and the coupled port of the directional coupler.

20. The signal amplification device of claim 19, wherein reactance of the capacitor has a same magnitude as the characteristic impedance of the directional coupler.
